(19) United States
(12) Patent Application Publication
(10) Pub. No.: US 2009/0266411 A1
(43) Pub. Date: Oct. 29, 2009

(54) PHOTOVOLTAIC WIRE

(75) Inventors: Youssef Habib, Lancaster, PA (US); John Steinbeck, Fitzwilliam, NH (US)

Correspondence Address: TED SABETY, c/o Sabety +associates, PLLC, 1130 Bedford Rd., PLEASANTVILLE, NY, 10570, US

(73) Assignee: ILLUMINEX CORPORATION, Lancaster, PA (US)

(21) Appl. No.: 11/917,505

(22) PCT Filed: Jun. 16, 2006
(86) PCT No.: PCT/US2006/023662

§ 371 Date: Jul. 16, 2008

Related U.S. Application Data
(60) Provisional application No. 60/692,026, filed on Jun. 17, 2005.

(51) Int. Cl. H01L 31/0248; H01L 31/04; C25D 5/00; H01L 31/0352

(52) U.S. Cl. 136/255; 205/112; 205/96; 257/21; 977/762; 257/E31.033

(57) ABSTRACT

A photovoltaic wire is presented where the active layers coat a metallic wire, preferably aluminum. The active layers are an array of doped silicon nanowires electrically attached to the metallic wire that extend from the surface of the wire into a layer of semiconducting polymer, preferably polyaniline. The surface of the polymer is coated with a transparent conductor to complete the photovoltaic circuit.

This application claims priority to U.S. Pat. No. 60/692,026, filed on Jun. 17, 2005, which is incorporated herein by reference.

This invention was supported in part by U.S. Government contract number 4200093584 awarded by NASA and portions of this invention may be subject to a paid-up license to the U.S. Government.

### BACKGROUND AND SUMMARY OF THE INVENTION

The present invention relates generally to a nanostructured photovoltaic device that can be formed as a ribbon, wire or thread (referred to herein as PV wire). This device has numerous applications in the conversion of light into electrical energy. Photovoltaics, or solar cells, are a means of generating electricity directly from sunlight. The utilization of solar energy can have a tremendous influence on the quest for clean, renewable power sources that provide an alternative to the current fossil fuel based energy sources. The PV wire structure consists of electrically conductive wire core, preferably aluminum, with substantially crystalline silicon nanowires protruding from the periphery in a bristle like fashion. The nanowires are further coated with a conducting polymer. The nanowire-polymer structures form a multitude of PV junctions. This architecture enables a lightweight, flexible solar cell platform designed for efficient and economic use of materials. This device uses ordered nanowire arrays which have the benefit of very strong optical absorption across the entire solar band.

Since the early 1990s, considerable attention has turned to organic thin-film photovoltaics based on easy to fabricate, low cost, soluble conducting polymers. For example, two-layer, thin-film polymer photovoltaics were described by M. Granstrom, K. Petritsch, A C. Arias, A. Lux A, M. R. Andersson, and R. H. Friend, Nature, 395:257-360. (1998). While charge generation in polymers is very efficient, charge separation and collection using nano-sized structures is more problematic. A new class of devices that relies upon the interaction between a nano-material and a conjugated polymer can overcome some of the difficulties by providing a large donor-acceptor interface. For example, Yu G, Gao J, J. C. Hummelen, F. Wudl, A. J. Heeger, Science 270: 1789-1791 (1995), describe charge separation and collection using nano-sized structures. By “nano”, it is meant structures and materials of any shape or morphology where at least one functional dimension is less than about 500 nanometers. There is a clear tradeoff between solar cell efficiency and weight that is of paramount importance for developing portable, point-of-use solar electric systems. In addition to enhancing photovoltaic conversion efficiency, the incorporation of nano-sized structures can improve photochemical, mechanical, and environmental stability. The use of hybrid:nanoscale inorganic structures embedded in organic polymers provides the engineering capabilities to tune the optical and electrical properties of the photovoltaics (parameters such as optical absorption and band gap) based on the dimensions of the nanostructures. This is described by W. U. Huynh, J. J. Dittmer, and P. A. Alivasatos, In Science, 295, 2425-2431 (2002) or M. Gratzel, In Inorganic Chemistry, 44, 6841-6851 (2005). The nanowire array architecture, when engineered on a thin aluminum wire, can have higher efficiency than thin film cells while retaining low weight. High photoelectric conversion efficiency can result due to the inherent light trapping arising from the nanowire array structure, the high mobility in the crystalline Si nanowires, the periodicity of the nanowires in the array, and the large photoactive surface area.

This invention is a novel photovoltaic device design where one embodiment is illustrated in FIG. 1. The silicon nanowires are produced directly on the surface of a thin aluminum wire by taking advantage of the self-organizational properties of anodic aluminum oxide (AAO). The array of nanowires grow substantially perpendicularly to the local surface of the wire and their position and cross sectional dimension are determined by the position and size of the pores within the AAO. It is well established that when aluminum is oxidized anodically in an acid electrolyte a porous structure is formed where the pores have a diameter of about 5 to 500 nm and are arranged in a quasi-hexagonal 2-D lattice. The pore diameter is a function of anodization voltage, electrolyte composition and concentration, while the pore depth is a linear function of anodization time. The AAO serves as a template for initial nanowire array formation. The array of nanowires grows substantially perpendicularly to the surface of the inner wire electrode and their position and cross sectional dimension are determined by the position and diameter of the pores within the AAO.

In the preferred embodiment, an n-type silicon nanowire array is initially seeded directly on the aluminum core while the bulk of each nanowire comprises either n-type or nominally undoped silicon (intrinsic or i). The length of the nanowires extends past the surface of the AAO. In the preferred embodiment the nanowires are crystalline silicon. A layer of semiconducting polyaniline (PANI) is used as the p-type portion of the p-n junctions that collect the electric charge pairs created by the incident photons. A p-type silicon layer can also be grown directly on the nanowires to further enhance the charge collecting properties of the junction area. Preferably the p-n all silicon junctions will have an n-type core with the p-type layer grown radially outward. The embedded nanowire design forms numerous p-n junction structures integral to the core of photovoltaic technology. A transparent outer conductor is applied to the PANI. Lastly, a transparent, high resistivity (dielectric strength) silicon resin, polyethylene, Teflon, polyimide or similar coating is applied to increase durability and protect the PV wire from wear, environmental degradation and electrical arcing. A longitudinal cross sectional schematic of the structure is shown in FIG. 2.

While the preferred embodiment for the nanowire based PV is a wire substrate, the versatility of the processing technique provides a means to create PV active nanowire structures on virtually any conducting surface upon which a layer of porous oxide with an array of pores can be electrochemically, evaporatively, or otherwise created.

This invention can provide light collection efficiencies that rival or exceed that of textured crystalline devices as a result of the nano-scale anti-reflective texture of the collecting surface. The array of nanowires acts as a anti-reflective light traps that improves absorption of light across the entire solar band. The salient features of the light trap are the textured tops of the nanowires and the high absorption structures formed by the array of wires. The optical absorption of the nanowires can be enhanced at a desired frequency by setting the dimensions of the nanowires for a resonance at that wavelength, further, the deep photonic structure of the array results in multiple internal reflections in the array each of which increases the absorption. Light entering the structure and reflecting from the top of a nanowire is scattered into the plane of the device from a very wide range of incident angles of the incoming light rays as shown in FIG. 8.

The innovative design of engineering the nanowires directly on the surface of a wire (thread) substrate makes it possible to construct large two and three-dimensional photovoltaic textile panels that are light-weight, can be stored in a small enclosure, and have high power density (specific power) in excess of 1000 W/kg. The primary application for the nanowire photovoltaic thread technology is the delivery of clean efficient point-of-use electric power, including the use of the PV wire to create photovoltaic fabrics (textiles) for sensor networks, tents, power patches for uniforms, solar sails for long term space exploration, and portable electronic devices. Other locations where PV fabric is useful include shelters, roofing, awnings, canopies, garments, plastics, portable electronic devices, battery charging, wireless devices, construction, and automotive applications. The invention can be incorporated into the surface of electronic device packaging (cases), permitting self-charging portable telephones, laptop computers, PDA's and other devices.

### BRIEF DESCRIPTION OF THE DRAWINGS

FIG. 1. Schematic view of the photovoltaic wire device showing silicon nanowires distributed about the metallic core.

FIG. 2. Longitudinal cross section schematic of the photovoltaic wire.

FIG. 3. Schematic of one embodiment of the specially shaped anodization cathode.

FIG. 4. SEM micrograph showing porous AAO on aluminum wire.

FIG. 5. Schematic of porous AAO on Al wire before barrier layer removal.

FIG. 6. SEM micrograph showing the Al wire, gold seeds, AAO and silicon nanowires.

FIG. 7. SEM micrograph of silicon nanowires with gold seeds at the tip.

FIG. 8. Schematic showing the paths of photons incident upon the nanowire array which lead to a large optical absorption

### DETAILED DESCRIPTION OF THE PREFERRED EMBODIMENTS

Periphery means the perimeter of a circle or other closed curve, the perimeter of a polygon, the external boundary or surface of a body and the outward bounds of something as distinguished from its internal regions or center.

Anodize means an electrolytic chemical reaction where a conductor is made the anode in order to coat the conductor with an oxide layer.

The photovoltaic wire invention presented here is produced by three basic steps: (1) producing a porous metallic oxide template structure on the surface of metallic wire or other substrate (2) inserting a catalytic seed in the oxide pores to initiate silicon nanowire formation of p, i (intrinsic), or n-type silicon nanowires, (3) growing the silicon nanowires out through the oxide pores, and (4) the application of n or p-type coating of polyaniline (PANI) or other similar conducting polymer to encase the silicon nanowire arrays and form a multitude of p-n junctions. In the preferred embodiment, the silicon nanowires are grown on aluminum, doped n-type and then coated with p-type polyaniline (PANI), forming a multitude of high surface area p-n junction structures. Practitioners of ordinary skill will recognize that although the preferred embodiment described here has the silicon nanowires doped as n-type and the PANI operating as p-type, the nanowires can be doped p-type and the PANI or other semi-conducting polymer can be doped to operate as a complimentary or n-type charge carrier to the doped silicon. Either is equivalent. In the preferred embodiment, the PANI is doped to become p-type and the inner Si nanowire doped to be n-type. Practitioners of ordinary skill will recognize that other conductive polymers can also be used, including in a manner to behave as a p-type or n-type resulting material. Further, it is easily recognized that the nanowire structures are not limited to silicon and can be made of Ge, GaSb, GaN, GaAs, InP, AlGaAs, GaInNAs or other semiconducting elements or compounds.

### 1. Anodization of the Conductor:

The photovoltaic wire is formed by the combination of the nanowires, a conductor and the charge carrier polymer coating. The nanowires that collect the electrical charges are electrically connected to the conductor, such that the substrate forms part of the electrical circuit. In order to form nanowires in an ordered array, a porous template is formed on the surface of the wire. The template is an oxide that is porous, that is, it has generally regular arrays of substantially vertically aligned pores with generally consistent widths, both in terms of statistical population as well as the vertical cross section of the pores. The porous template can be made of titania (TiO₂), silica (SiO₂), zinc oxide (ZnO₂), zirconium oxide, lanthanum oxide, niobium oxide, tungsten oxide, tin oxide, indium oxide, indium tin oxide (ITO), strontium oxide, vanadium oxide, molybdenum oxide, calcium/titanium oxide, or blends of two or more such materials. In the preferred embodiment, anodic alumina, Al₂O₃ is used as the template. The anodic aluminum oxide layer on the Al wire substrate serves as a template for the formation of nanometer scale nanowire arrays in accordance with this invention where the nominal diameter of the nanowires is determined by and approximately the same diameter as the AAO pores.

It is well established that electrochemical oxidation of aluminum can result in the growth of porous Al₂O₃ as described by D. Al Mawlawi, C. Douketis, T. Bigioni, M. Moskovits, et. al. in Electrochemical Fabrication of Metal and Semiconductor Nano-wire Arrays, Electrochemical Society Proceedings, Volume 95-8, pp. 262, incorporated herein by reference. The basic process for creating porous Al₂O₃ has been known for over 40 years and has been used extensively to create colored aluminum, as disclosed in S. Wernick, R. Pinner, and P. G. Sheasby, The Surface Treatment and finishing of Aluminum and its Alloys Volume 1, 369 Finishing Publications Ltd., Middlesex England, (1987). Recently, there has been renewed interest in porous aluminum oxide technology for making ordered arrays of nanochannels, as disclosed by Dmitri Routkevitch, Jimmy Chan, Dmitri Davydov, Ivan Avrutsky et. al. in Electrochemical Fabrication of the Nano-wire Arrays: Template, Materials and Applications, Mat. Res. Soc. Symp. Proc., Vol. 451, 1997, Materials Research Society, pp. 367, J. Chen, Appl. Phys. Lett, 74, 2951 (1999) and D. Crouse, Y-H Lo, A. E. Miller, and M. Crouse, Appl. Phys. Lett. 76, 49 (2000). The use of anodized alumina as a template for nano-structures is known in the art, as described by J. Westwater, D. P. Gosain, S. Tomiya, and S. Usui, J. Vac. Sci. Tech. B 15, 554 (1997); X. H. Fan, L. Xu, C. P. Li, Y. F. Zheng, C. S. Lee and S. T. Lee, Chem. Phys. Lett. 334, 229 (2001); K. K. Lew, L. Pan, T. E. Bogart, S. M. Dilts, E. C. Dickey, and J. M. Redwing, Appl. Phys. Lett., 85, 3101-3103. (2004); X. Duan, J. Wang, and C. M. Lieber, Appl. Phys. Lett. 76, 1116 (2000) and X. Duan and C. M. Lieber, Adv. Mat. 12, 298 (2000)

This invention uses an improved method of creating the anodic aluminum oxide template so that it is particularly well formed for use as a template to create nanowires in a manner compatible with semiconductor device fabrication processes. The diameter, depth, and spacing of the pores can be controlled by varying the anodization voltage and the type and concentration of electrolyte used. In addition, the layer is created in a manner that makes it of uniform depth across the surface of the wire on all sides. One novel aspect of the process is that because the metallic wire itself is the substrate for the device, the anodization process can be operated using the wire substrate as the electrode for carrying the anodic current. In the preferred embodiment, the aluminum wire substrate acts as the surface that forms into the porous oxide template. In the preferred embodiment, the conductor is a wire. Practitioners of ordinary skill will recognize that a conductive coating can be applied to a ribbon, fiber or filament and such structure is equivalent to a wire as described herein.

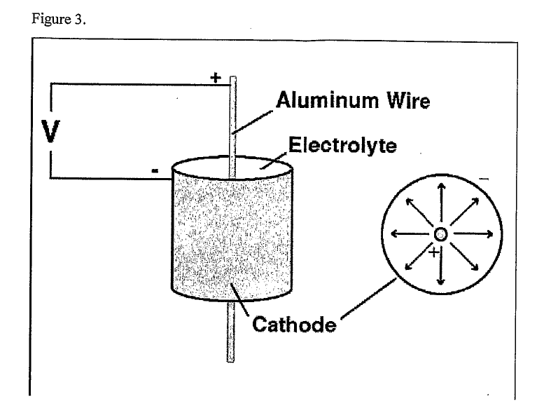

A key feature of the process is the use of a specially shaped cathode that surrounds the segment of the conductor as part of the anodization process as shown in FIG. 3. The cross sectional shape of the cathode is formed in a manner that induces a substantially uniform electric field at the surface of the conductor along the longitudinal segment of the wire substrate being anodized and around the axial cross sectional line at the surface of the conductor. In one embodiment this is achieved by using a substantially cylindrical cathode around a substantially cylindrical wire as shown in FIG. 3. The uniformity of the electric field causes an anodization process that is uniform across the surface of the conductor. The result is the creation of a sufficiently uniform porous oxide layer in all respects to depth, ordering, pore diameter and spacing prior to the remaining steps in the process of creating the photovoltaic device.

This aspect of the process allows nanowire arrays to be assembled with a uniform density using a variety of substrates, including flat solid substrates, wires of a variety of cross sections flexible substrates, conformally coated surfaces and/or the outer surfaces of ribbons or fibers. In addition, one can control the length, diameter and center-to-center spacing of the nanowires in the array, which facilitates tuning the array to a particular excitation wavelength. Additionally, the density of the nanowires may be chosen to provide an array with a number of nanowires per unit area adapted to maximize the photovoltaic output. For example, the lengths may range from 5 nm to 200 microns, preferably up to 100 microns long, and nanowire densities from 10⁸ cm⁻² to 10¹² cm⁻². In one embodiment, the nanowires extend past the oxide layer between approximately 10 nanometers and 5 microns, and in another embodiment, between approximately 5 microns and 30 microns.

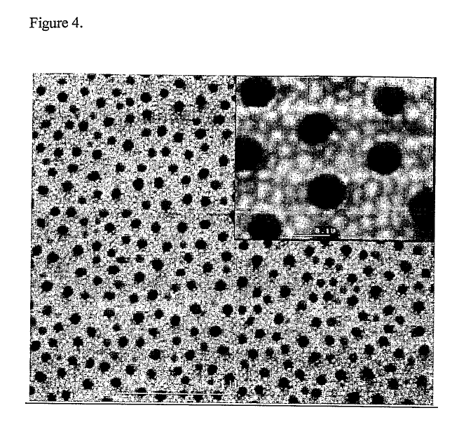

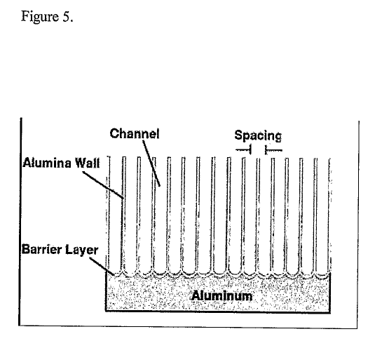

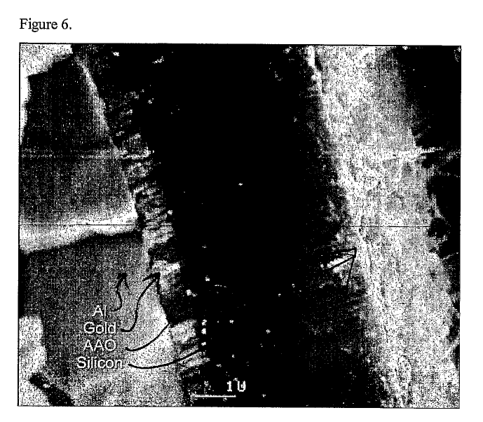

The initial anodization step creates a porous anodized layer about the outer periphery of the conductor segment being anodized between about 1 and 15 μm thick. In the preferred embodiment, an alumina barrier is formed at the bottoms of the pores (or channels) as shown schematically in FIG. 5. In the preferred embodiment, the substantially cylindrical aluminum (Al) wire anodization for the photovoltaic wire is carried out using a substantially cylindrical stainless steel mesh cathode with the Al wire placed at the center. This geometry produces a uniform porous AAO structure about the surface of the entire wire due to the uniform field distribution. In this step, Al wire with nominal diameters of about 100 to 300 μm can be anodized, although thick or thinner wires may be used as required by the application. FIG. 4 shows an SEM image of the anodization layer with the pores

In the preferred embodiment, high purity approximately (99%) aluminum wire is used as a the base material for the device. The wire is electropolished in an approximately 1:3 sulfuric/phosphoric acid bath to remove most of the manufacturing marks and defects on the surface. The polished wire is anodized in acidic electrolyte bath at approximately 10 to 100 V to create a nanoporous array matrix with the nanopore diameter of approximately 10 to 100 nm and a pore depth of about 1-5 μm.

The aluminum wire can be anodized using a range of voltages, electrolyte concentrations and pore widening times to produce pores with diameters from between approximately 20 to 150 nanometers (nm) and center-to-center spacing from approximately 30 to 300 nanometers. The anodization is typically carried out in a solution of between approximately 0.01 and 1 percent by weight acidic electrolyte at between approximately 10 and 200 volts DC. Other concentrations of acidic electrolyte and voltages can be used with varying results, including the time required to produce the appropriate thickness of anodic alumina. A reasonable range of control can be achieved in making the porous AAO on Al wire with a range of pore diameters and spacing. The AAO structure directly impacts the dimensions, and consequently, the optical properties of the silicon nanowire arrays. The AAO pore diameter and spacing is a function of anodization voltage, electrolyte type, concentration, and pore widening time. The diameter of the semi-conducting nanowires is determined by the AAO pore diameter, which is largely retained after the nanowires grow out beyond the surface of the AAO template. The AAO pore spacing determines the initial nanowire spacing. Once the nanowires protrude more than a few micrometers from the AAO surface, they begin to bend and overlap one another. The thickness of the AAO layer affects device performance. AAO is a very hard material that will stress crack if it is too thick, but it can be a robust component of the PV thread with appropriate thickness. Once the polymer coatings are applied, some cracking of the AAO is tolerable.

A step-down voltage procedure can be used to reduce the thickness of the oxide barrier layer that inherently forms as the oxide growth front at the bottom of the pores (or channels). In the preferred embodiment, the step-down voltage technique is used to substantially reduce remnant aluminum oxide from the bottom of the pores in order to clear a low resistance electrical path to the Al (or other substrate) metal core. The step down procedure is comprised of reducing the anodization voltage until the anodization current is nearly stabilized. Since conduction through the barrier oxide is a tunneling process, the saturation of the anodization current at a particular voltage can be used to gauge the barrier layer thickness. In the preferred embodiment, the anodization voltage is stepped down from the initial growth voltage to approximately 20 VDC in a range of 1 to 10 V steps. Subsequent to the stepping down of the anodization voltage, the current rises and then plateaus, at the plateau, the voltage is again reduced.

After anodization and step down, the pores can be widened and any remaining oxide barrier layer removed by etching in a phosphoric acid bath at approximate 37° C. for about 15 minutes, although other temperatures and times may be used with varying results. In the preferred embodiment, the resulting pore diameters range from 50 to 100 nm depending on the anodization voltage and the pore widening time. Likewise, the center-to-center spacing varies from about 100 to 200 nm. Representative samples imaged using a SEM, showing the porous AAO layer on the surface of an Al wire is shown in FIG. 4. At this stage the wires are ready for catalytic seed insertion.

The PV wire can be engineered using a solid conductor substrate or conductive coating on another surface or aluminum coated on another conducting core. Embodiments of the latter include, for example: an ITO or other transparent conductor coated on a glass surface followed with an Al layer about 1 to 100 μm thick applied by evaporation or sputtering, a copper, silver, gold or other metallic wire (cylindrical or otherwise) similarly coated with Al, an insulating substrate coated with a conducting polymer followed by an Al layer about 1 to 100 μm thick, a metal foil or sheet coated with an Al layer, a flexible insulating plastic coated with a conductor and then an Al layer, a two conductor layered mesh, or virtually any conducting surface to which an Al layer can be applied by electrodeposition, evaporation, or sputtering. Anodization of the Al layer can be carried out as with the previously described all Al substrate, given an underlying conductor through which the anodization current can flow. The need for a voltage step down procedure is eliminated as the pores will mostly penetrate through the anodized Al to the underlying conductor. A phosphoric acid pore widening step is sufficient to clear any remnant oxide from the AAO/conductor interface. The use of a conducting substrate other than Al adds the advantage of having a distinct discontinuity in the anodization current that occurs when the AAO consumes the entire Al layer. It may be necessary to mask off the conducting surface that is not coated with Al with an insulating material during the anodization process to avoid a chemical reaction with the conductor and the anodization bath. Subsequent to formation of an AAO porous template, the gold seeding, nanowire growth, and polymer coating is carried out. The conductive layer finally serves as one electrode for the PV device.

In one embodiment, a copper sheet about 1 mm thick is coated with about 2 μm of Al. The backside of the copper sheet is masked by resist materials such as Teflon, polyimide, polyethelene, a silicon resin or other chemical resist material that can be readily applied by spraying, dipping or brushing on. The anodization is carried out as described producing an approximately 3 μm thick layer of porous AAO. During the approximately 1 hour anodization process, the current reaches a steady state value after about 2 to 5 minutes which is maintained until the Al metal is consumed and converted to AAO. At this point the anoditation current rises to approximately 2 to 3 times its steady state value and can thus be automatically monitored and switched off using a current activated circuit breaker for ease of manufacture. Alternatively, a computer can monitor the current by means of well known analog to digital conversion techniques, and when the predetermined current profile is detected, the computer can cause a relay to break the circuit. Following anodization, the pores can be widened and remnant Al₂O₃ cleared from the bottom of the pores at the copper interface in a an approximately 5 to 25 wt % solution of phosphoric acid. A catalytic seed of gold, tin or other catalyst material is inserted in to the bottom of the pores at the conductor/AAO interface by AC electrodeposition. Subsequently the masking material is removed by peeling for dissolution in a solvent and Si nanowires are grown using standard CVD VLS growth process well known in the art.

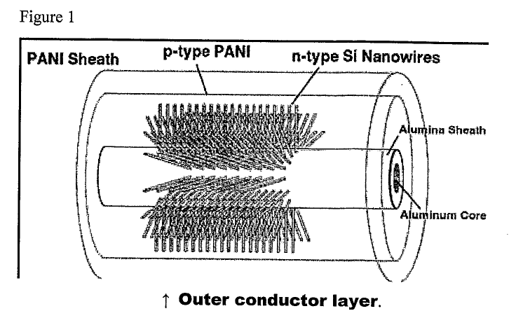

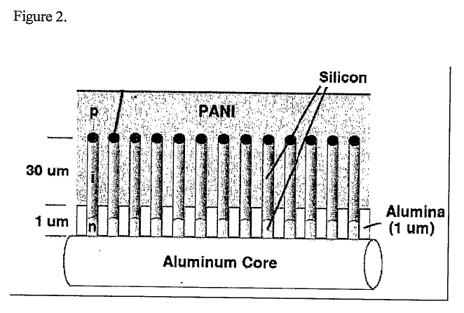

In another embodiment, a nanowire PV device is created on a glass substrate. The first step is to produce a porous AAO template using a high purity Al thin film coated onto the surface of glass slides. A thin (approximately 100 nm) indium tin oxide (ITO) conductive layer (20 Ω/square) will be deposited on the substrates before the Al for use as an electrode when electrodepositing the metals to form Si nanowire catalytic seeds. The anodization is carried out until all the Al metal is consumed and the channels in the Al₂O₃ penetrate through to the ITO strike layer. Anodization is performed at about 20 to 200 V dc depending on the desired pore diameter and spacing. As the Al₂O₃ pores begin to penetrate the Al/ITO interface, the anodization current begins to increase. When the current reaches approximately 2 to 3 times its steady state value, this indicates that the Al metal has been consumed and the anodization process is stopped. At this point the samples appear translucent and porous structures are formed as presented in FIG. 1. Following anodization, the pores can be widened and remnant Al₂O₃ cleared from the bottom of the pores at the ITO interface in a 5 to 25 wt % solution of phosphoric acid. The ITO serves as an electrode for the PV wire. Gold seeds are then prepared inside the porous AAO by standard AC electrolysis. Silicon nanowire growth is produced using the vapor liquid solid growth technique, which is well known in the art. Finally, the nanowires are drip coated with PANI or another polymer followed by a final transparent conductive coating.

### 2. Catalytic Seed Insertion.

Metallic seeds can be used to catalyze the growth of the silicon nanowires on the bulk metallic wire by inserting small amounts of material into the AAO pores at the clearing to the underlying conductive material or wire. The catalytic growth of silicon and other semiconductor nanowires using gold seeds is a well established process. For example, such a process is described by Kok-Keong Lew, Cordula Reuther, Altaf H. Carim and Joan M. Redwing, Template-directed vapor-liquid-solid growth of silicon nanowires, Rapid Communications, J. Vac. Sci. Technol. B 20 (1), January/February 2002, American Vacuum Society, pp. 389, which is incorporated herein by reference. Gold is readily deposited into the porous AAO nanopores by electrochemical methods. In the preferred embodiment, gold (Au) seeds are deposited at the bottom of the AAO pores by alternating current (AC) electrodeposition. The electrodeposition bath comprises a solution of commercially available gold sulfite in deionized water.

The Au seeds are electrochemically deposited into the anodized wire pores using pulse plating. Gold seeds are used for vapor, liquid, solid (VLS) growth of silicon nanowires, primarily due to the low Au—Si eutectic temperature (363° C.) and favorable wetting properties, which result in the formation of a stable liquid alloy phase at the silicon nanowire tip. In the preferred embodiment, the diameter of the Au seeds are between approximately half the diameter of the pores to the diameter of the pores themselves.

The use of the wire or metallic substrate as part of the photovoltaic circuit provides the advantage of using the wire substrate itself as the electrode for the electrolysis current. This ensures that the Au seeds are deposited at the surface of the conducting substrate resulting in the nanowires growing directly on the conducting wire substrate itself, making an ohmic contact. An SEM micrograph showing the Al wire at the bottom, then the gold seeds and the porous AAO matrix on top is presented in FIG. 6. The pores are about 12 μm deep and the gold seeds are clearly shown at the bottom, as is the rounding of the wire underneath.

Gold is the most common metal used as a catalyst for vapor-liquid-solid (VLS) growth of silicon nanowires, primarily due to the low Au—Si eutectic temperature (363° C.) and favorable wetting properties which result in the formation of a stable liquid alloy phase at the nanowire tip. However, it is well known that gold forms deep level states within the bandgap of silicon which act as recombination centers for minority carriers in both p-type and n-type material. While the solid solubility of gold in silicon is low (<10¹³ cm⁻³) at temperatures typically used for VLS growth of silicon nanowires (˜500° C.), it is possible that metastable amounts of gold may be incorporated in the nanowire since the silicon crystal precipitates out of a liquid gold melt in this growth process. Consequently, it is important to identify alternative metals that act as effective solvents for VLS growth of silicon nanowires without incorporation of electrically active impurities.

A variety of elements have been demonstrated to act as solvents for VLS growth of Si nanowires including, for example, group I elements (Ag, Cu) and transition metals (Pt, Pd, Ni). In addition, Ga may be used. Similar to Au, Ag also has a low solid solubility in Si at 500° C. (<10¹³ cm⁻³) but forms two mid-gap states which may act as centers for carrier recombination. However, Ag is significantly lower in cost than Au and can be easily electroplated. An interesting alternative catalyst which will be explored in this program is Sn. A Si—Sn liquid phase forms at temperatures greater than ˜600° C. Early studies demonstrated epitaxial growth of Si thin films beneath a layer of Sn at temperatures on the order of 500-650° C. due to a vapor-liquid-solid mechanism.

Furthermore, since Sn is a group IV element, it is isoelectronic in silicon. Consequently, even though the solid solubility of Sn in silicon is substantial at 600° C. (>10¹⁸ cm⁻³), it does not readily form deep level states as is the problem with Au and Ag. In another embodiment, aluminum itself can act as the catalyst, which fortuitously in the preferred embodiment, is the wire substrate. However, this requires operating the reaction chamber at higher temperatures.

### 3. Catalytic Growth of Silicon Nanowires

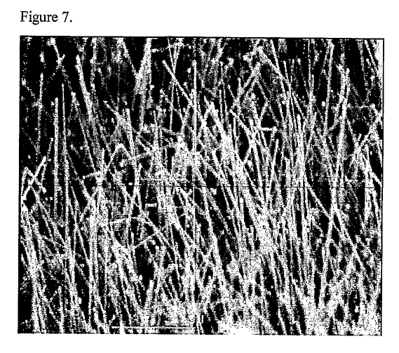

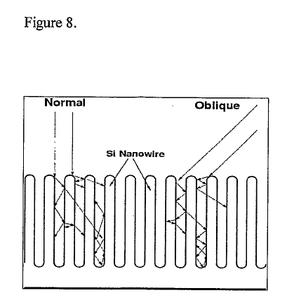

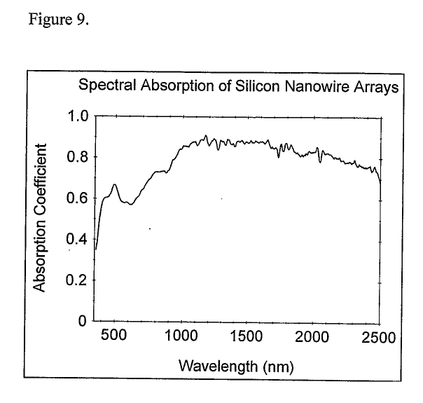

The aluminum wire with the seeded AAO template layer are heated to an appropriate temperature in a reaction chamber and silane (SiH4) is introduced. A catalytic reaction between the silane and the gold seeds results in the formation of a Au—Si alloy at temperatures above the eutectic temperature (about 363° C.). A single crystal silicon nanowire is then precipitated from the liquid alloy when it becomes supersaturated with silicon. Since the nanowires nucleate randomly within the pores, the nanowires exhibit a variety of crystal growth orientations including <111>, <112>, <110>, and <100>. The silicon nanowires can be doped p-type and n-type with controlled resistivity using trimethylboron and phosphine dopant sources, respectively. In the preferred embodiment, doping ratios for the n-type growth are between approximately 10⁻³ to 10⁻⁵ phosphine:silane, although higher and lower concentrations may be used with varying results. In the preferred embodiment, the silicon nanowires are grown by vapor-liquid-solid (VLS) growth at a temperature of 500° C. in an isothermal quartz tube reactor. The samples are placed in a quartz boat and situated in the middle of the tube furnace. Alternatively, the wire can be continuously fed through a reaction tube for production systems. The system is degassed under vacuum and purged with N₂. The process gas is then switched to H₂ as the furnace is heated to the growth temperature of about 400 to 500° C. Then SiH₄ (10% in H₂) is introduced into the reactor as the Si source gas to initiate nanowire growth. In the preferred embodiment, the nanowires are doped n-type by the addition of phosphine (PH₃, 100 ppm in H₂) during growth although other donor dopants can be used. Practitioners will recognize that the nanowire can alternatively be doped p-type by the use of Trimethylboron (TMB) or other dopants. The gas pressure is between approximately 1 to 13 Torr. The growth time is between 15 and 240 minutes to produce nanowires with a length of between 5 and 25 μm protruding from the AAO surface. As the silicon nanowires form, part of the gold seeds grows out on the tips of the nanowires. FIG. 7 shows an SEM of the silicon nanowires with gold seeds at the tip.

Practitioners of ordinary skill will recognize that the reactive temperatures, vessel pressure and gas concentrations may be adjusted higher or lower with varying results, depending on the specific desired doping concentration, electrical properties or other characteristics sought and the type of catalytic seed used. Different doping gases can be used as well. For example, the Si nanowires can also be grown at temperatures of 450 to 700° C., with higher temperatures to be used with the Sn catalytic seeds. It is also possible to grow a p-type Si coating over the n-type nanowires. The n-type nanowires are grown first and removed from the furnace to determine if any residual seed material is left. If there is, this is etched and then the p-type coating is grown using Trimethylbaron (TMB) as a dopant gas in the approximately the same ratios to silane as used for the phosphine. The p-type growth is done at approximately 600° C. This is further described by K. K. Lew, L. Pan, T. E. Bogart, S. M. Dilts, E. C. Dickey, and J. M. Redwing, Appl. Phys. Lett., 85, 3101-3103 (2004), incorporated herein by reference.

It is evident that the catalytic seed serves no purpose once the silicon nanowire is grown. The gold can cause an electrical shorting effect during the optical and electrical operation of the device. The presence of the gold lowers the resistance of the samples, reduces carrier lifetime, and acts as a recombination site. To avoid this, the minimal amount of gold possible to initiate eutectic silicon nanowire growth is used, however, excess remant Au tips are etched away after the nanowires are grown in a KI/I₂ solution for 30 minutes at room temperature. The etch rate is about approximately 20 to 30 angstroms per second. GE-88110 or 88111, a gold etch solution from Transene, Inc., located in Danvers, Ma., may be used.

Radial p-n Si nanowire junctions are an alternative type of structure. This geometry offers improved efficiencies over organic thin film cells since the nanowires can be very long in the axial direction for maximum light absorption but much shorter in the radial dimension for improved collection of photogenerated carriers. The optimum radius of the nanowire core should be approximately equal to the minority carrier diffusion length (for materials like amorphous Si with low diffusion lengths, approximately 100 nm). Enhanced light trapping results from this geometry. For the radial p-n junctions, epitaxial Si thin films are deposited on the outer surface of the templated silicon nanowire structures to form a shell layer using a low pressure CVD system. Practioners of ordinary skill will recognize that silicon nanowires that contact the p-n junction are not coated with a conjugate charge carrier polymer, but only the conductive electrode layer. This all silicon p-n nanowire junction embodiment provides a high interface area along the entire radial directions of the n-type core.

4. Coating with Semi-Conducting Polymer.

The nanowire arrays of this invention are coated with a semi-conductive polymer such as Polyanalyne (PANI), Polyacetylene (PA), Polythiophene (PT), Poly (3-alkyl) thiophene (P3AT), Polypyrrole (PPy), Polyisothiaphthene (PITN), Polyetheltene dioxythiophene (PEDOT), Polyparaphenelyne vinylene (PPV), Poly (2,5 dialkoxy) paraphenylene (MEH-PPV), Polyparaphenylene (PPP), Polyparaphenylene sulphide (PPS), Polyheptadiyne (PHT). The polymers can be n- or p-type forming a multitude of junctions with the nanowires at the nanowire-polymer interface. In the preferred embodiment, the preparation of PANI for coating Si nanowires is used.

Doping conjugated polymers by chemical or electrochemical methods can be accomplished over the full range from insulator to metal by introducing the desired carriers into the electronic structure. The repeated units comprising the macromolecules are potential redox sites. Consequently, conjugated polymers can be doped n-type by reduction or p-type by oxidation, as disclosed by A. J. Heeger, Semiconducting and Metallic Polymers: The Fourth Generation of Polymeric Materials, Nobel Lecture, Journal of Physical Chemistry B, 105, 4875-4891 (2001), incorporated herein by reference.

In the preferred embodiment, polyaniline is used due to its outstanding properties. It is one of the so-called doped polymers, in which conductivity results from a process of partial oxidation or reduction. Polyaniline compounds can be designed to achieve the required conductivity for a given application. The resultant blends can be as conductive as silicon and germanium or as insulating as glass, as disclosed by S. C. Kim, D. Sandman, J. Kumar, F. F. Bruno, and L. A. Samuelson, Chemistry of Materials, 18, 2201-2204 (2006), incorporated herein by reference.

The junctions formed at the interface between the surface of the Si nanowire and the conducting polymer is very critical because this is where the useful electron-hole pairs produced by incoming photon radiation (light) are generated and then collected by the complementary charge carrier layers at the interface. Bound electron hole pairs created in the polymer are excitons and charge collection occurs within the exciton diffusion length (about 10 to 20 nm). In a typical scenario, photons are absorbed in the polymer creating an exciton and subsequently an electron is transferred to the silicon nanowire, however, the photons can also be absorbed in the silicon and a hole can be transferred to the polymer. Either process will result in a net photovoltaic current flow. Practitioners in the art will recognize that if the nanowire were p-type and the polymer n-type the reverse transfer will occur. A proper conductive coating is necessary to complete the electrical circuit from the polymer to the Al core and re-supply electrons drawn away as photocurrent.

Silicon will quickly oxidize in air forming an amorphous native oxide layer 2-3 nm thick. This native oxide can be removed from the nanowires using a buffered oxide etch (BOE) for 3-5 minutes at room temperature. This oxide can impair charge collection. The nanowires need to be coated when clean, using an oxide etch step and coated with polyaniline quickly to avoid re-oxidation, or stored in an inert environment such as nitrogen or argon gas until coating. This prevents the native oxide from forming between the PANI and the Si nanowire surface. Presence of the oxide limits the quality of the resulting device.

The etch of the oxide takes place using a buffered solution containing hydrofluoric acid: the device is quickly dipped in the bath and then rinsed with deionized water. The buffered HF solution is characterized by a high buffer index and an optimized, uniform oxide-etch rate. This is etch is available from Transene, Inc. and is called Buffer HF Improved. The solution is used at about room temperature and the etch rate is about 800 Å/minute. Practitioners of ordinary skill will recognize that as an alternative to etching the native oxide, the entire reaction growing the Si nanowires can be performed without any oxygen in order to prevent the growth of the oxide. Subsequent to nanowire growth, the device can be moved into a zero oxygen environment chamber where the polymer conductor is added. In this manner, the native oxide problem is mitigated by simply avoiding the presence of oxygen. Practitioners of ordinary skill will also recognize that the hydrofluoric acid etch step can be performed in a zero oxygen environment so that the native oxide does not reform before the polymer layer is added and that a zero oxygen environment should be maintained until the device is coated by the polymer.

Practitioners of ordinary skill will recognize that dangling bonds form on clean semiconductor surfaces, and these readily react with water, oxygen or carbon dioxide to form a so called native oxide layer on silicon. HF treatment removes the oxide and leads to H terminated surfaces. These bonds are resistant to re-oxidation for short durations. Further processing with the conductive polymer layer, especially PANI, exploits the Hydrogen bond and creates a viable contact across the Si—PANI interface.

Besides etching using HF, reduction in H₂ or NH₃ at about 50 to 200° C. for about 1 to 10 hours will remove the native silicon oxide layer from the nanowire. Passivation using elements like hydrogen, fluorine, selenium and sulfur can also be used. Passivation can also be achieved by forming Si—N. Each of these alternatives provide different operating characteristics. In the preferred embodiment, the HF etch is used and the PANI layer applied promptly.

The preparation of conductive polyaniline (PANI) polymer for coating nanowire arrays is based on the method described by R. Madathil, R. Parkesh, S. Ponrathnam and M. C. J. Large, Macromolecules, 37, 2002-2003 (2004), incorporated herein by reference. This method employs the formation of a gel in an aqueous aniline-dodecylbenzenesulfonic acid micellar suspension. The use of an aqueous suspension allows for the formation of films by dip or drop coating prior to gelation. Dodecylbenzenesulfonic acid serves as a surfactant dopant to provide electrical conductivity in the polyaniline gel. An aqueous suspension is suitable for the formation of thin-films by dip or spray coating and holds the prospect of high throughput manufacturing using a reel-to-reel process. In the case where silicon nanowires are grown from a substrate, for example a glass/ITO/Al₂O₃ substrate, PANI deposition using an eye dropper is superior to dip coating.

Doped PANI was prepared by doping polyemeraldine base with dodecylbenzene sulfonic acid (DBSA). Other surfactant dopants including camphor-sulfonic acid (CSA) and p-toluenesulfonic acid (pTS) can be used in the preparation of PANI films with varying results. In the preferred embodiment, the precursor solution is prepared by dissolving approximately 4 to 10 g of emeraldine precursor per liter of N-methylpyrolidone (NMP) with approximately 1 M concentration of the acid to be used to dope the polyaniline.

In the preferred embodiment, a 0.025 M stock solution of dodecylbenzene sodium sulfonate (available from Spectrum Chemical Mfg. Corp., New Brunswick, N.J.) is prepared by dissolving 4.35 g in 500 mL of de-ionized water and stirring until dissolution. The acid form, dodecylbenzene sulfonic acid (DBSA), is formed by the addition of 16.5 mL of 1 M HCl. Working solutions are prepared by slowly adding 50 to 150 μL of aniline (available from Alfa Aesar, Ward Hill, Mass.). Polymerizing agent, ammonium persulfate (available from E.M. Science), is added to the aniline-DBSA suspension and stirred to dissolution. The electrical conductivity of polyaniline is controlled up to 10 Siemens/cm by dissolving the emeraldine precursor in protonic acids leading to an internal redox reaction. The PANI coating mixture is adjusted to provide the best coverage over the nanowires and complete contact along the vertical surfaces of them. The mixture is adjusted depending on the geometry of the nanowire array being covered.

Practitioners of ordinary skill will recognize that PANI or other conductive polymers have inherent charge carrier characteristics that can be relied on without doping to create a device, although the characteristics of the resulting device will be different than the preferred embodiment. The preferred embodiment uses polyaniline (emeraldine) as the conducting polymer. Additional conducting polymers such as poly(1,4-phenylene vinylene), poly(pyrrole), and polyacetylene can be used. The use of doping agents for the polymer, for example, AsF₃, I₂, CN and other elements can be used.

### 5. Electrode and Protective Coating.

Subsequent to the polymer coating, the PV wires are all or partially coated with a substantially transparent and preferably, flexible conductor for use as an outer electrode. An outer coating of Indium Tin Oxide (ITO) can be used, however, ITO suffers from its inherent brittleness, the necessity of a vacuum sputter deposition process, and high cost. Alternatively, one can use a new type of coating consisting of carbon nanotubes bound in a polymer, Invisicon, that is produced by Eikos Inc., and described in U.S. Pat. No. 7,060,241, issued Jun. 13, 2006. This coating is highly flexible, can be spray or dip applied, and has greater than 90 percent visible light transmittance with a sheet resistance of 2001/square. The coating is also robust. Tensile strain analysis shows a 14 percent change in resistance at an 18 percent strain compared to a 20,000 percent change in resistance at a 3 percent strain for ITO films.

A final coating for protecting the PV wire from wear, the environment and electric breakdown may be added to the device. The cladding material can be applied before or after weaving the PV wires into a fabric. The sequence depends on the type of fabric, its weave and the target application, among other factors. This coating must be flexible, robust, transparent, and inexpensive. One material is a flexible transparent modified silicone resin conformal coating. This coating has a useful temperature range of −70 to 200° C., and is resistant to UV breakdown, electrical arcing and is currently used in aerospace applications. Another option is to use a liquid polyimide wire coating. Other possibilities are Teflon or polyethelene. An undesirable feature of any coating would be where the coating has a reflectivity that is high or any other type of optical interference.

Optical absorption tests show a strong absorption across the part of the solar band important for PV energy conversion as shown in FIG. 9. This result demonstrates the anti-reflective properties of nanowire arrays. In addition, the strong absorption in the infrared opens up the possibility of engineering a thermovoltaic device using GaSb, InGaSb, or InGaAsSb or other low band gap semiconducting nanowire structures. Practitioners of ordinary skill will recognize that absorption of infrared wavelengths into the nanowire array produces charge pairs and hence current. Many sources of heat produce infrared radiation but not visible light. The behavior of the PV wire in the infrared permits its use as an electrical energy source in the presence of waste heat.

Although the present invention has been described and illustrated in detail, it is to be clearly understood that the same is by way of illustration and example only, and is not to be taken by way of limitation. It is appreciated that various features of the invention which are, for clarity, described in the context of separate embodiments may also be provided in combination in a single embodiment. Conversely, various features of the invention which are, for brevity, described in the context of a single embodiment may also be provided separately or in any suitable combination. The spirit and scope of the present invention are to be limited only by the terms of the appended claims.

1. A photovoltaic device comprising:
An insulating porous layer that substantially coats a portion of a surface of a first conductor, said porous layer having a plurality of pores, each pore having a bottom substantially at the surface of the first conductor and an opening at the opposing surface of the porous layer,
A semiconducting layer that at least partially covers the opposing surface of the portion of the porous layer;
A second conductor that at least partially covers the semiconducting layer; and
A plurality of semiconducting nanowires, each with two ends, where at least one of the semiconducting nanowires pass through one of the pores where the first end of said at least one semiconducting nanowires is electrically connected to the first conductor at the bottom of the pore and the second end of said at least one semiconducting nanowires extends substantially past the opening of the pore into the semiconducting layer.

2. The photovoltaic device of claim 1 where the semiconducting nanowire is comprised of silicon.

3. The photovoltaic device of claim 2 where there is substantially no oxide layer between the semiconducting nanowire and the semiconducting layer.

4. The photovoltaic device of claim 1 where there is substantially no barrier layer between the bottom of the pores and the surface of the first conductor.

5. The photovoltaic device of claim 2 where there is substantially no barrier layer between the bottom of the pores and the surface of the first conductor.

6. The photovoltaic device of claim 1 where the semiconducting nanowire extends between approximately 10 nanometers and 5 micron past the outer surface of the porous coating layer.

7. The photovoltaic device of claim 6 where the semiconducting nanowire is comprised of silicon.

8. The photovoltaic device of claim 7 where there is substantially no oxide layer between the semiconducting nanowire and the semiconducting layer.

9. The photovoltaic device of claim 1 where the semiconducting nanowire extends between approximately 5 microns and 30 microns past the outer surface of the porous coating layer.

10. The photovoltaic device of claim 9 where the semiconducting nanowire is comprised of silicon.

11. The photovoltaic device of claim 10 where there is substantially no oxide layer between the semiconducting nanowire and the semiconducting layer.

12. The photovoltaic device of claim 1 where the semiconducting nanowire extends between approximately 30 microns and 200 microns past the outer surface of the porous coating layer.

13. The photovoltaic device of claim 12 where the semiconducting nanowire is comprised of silicon.

14. The photovoltaic device of claim 13 where there is substantially no oxide layer between the semiconducting nanowire and the semiconducting layer.

15. The photovoltaic device of claim 1 where there the plurality of semiconducting nanowires are spaced between approximately 10 nanometers to 100 nanometers center to center.

16. The photovoltaic device of claim 1 where there the plurality of semiconducting nanowires are spaced between approximately 100 nanometers to 500 nanometers center to center.

17. The photovoltaic device of claim 1 where the plurality of semiconducting nanowires have diameters between approximately 10 nanometers to 100 nanometers.

18. The photovoltaic device of claim 1 where the plurality of semiconducting nanowires have diameters between approximately 100 nanometers to 500 nanometers.

19. The photovoltaic device of claim 1 where the plurality of semiconducting nanowires have a density between approximately 10⁸ cm⁻² and 10¹² cm⁻².

20. The photovoltaic device of claim 1 where the thickness of the porous coating is between approximately 50 nanometers and 500 nanometers.

21. The photovoltaic device of claim 1 where the thickness of the porous coating is between approximately 500 nanometers and 50 microns.

22. The photovoltaic device of claim 1 where the thickness of the porous coating is at least approximately 500 nanometers thick.

23. The photovoltaic device of claim 1 where the semiconducting nanowire is an n-type semiconductor and the semiconducting layer behaves with a p-type charge carrying property.

24. The photovoltaic device of claim 1 where the semiconducting nanowire is a p-type semiconductor and the semiconducting layer behaves with an n-type charge carrying property.

25. The photovoltaic device of claim 1 where the semiconducting nanowire is doped n-type beginning at approximately the tip of the first end and for a predetermined distance along its length and substantially un-doped throughout the remaining length and the semiconducting layer behaves with a p-type charge carrying property.

26. The photovoltaic device of claim 1 where the porous coating is an oxide of the first conductor.

27. The photovoltaic device of claim 1 where the porous coating is aluminum oxide.

28. The photovoltaic device of claim 1 where the porous coating is one of either: titania, silica, zinc oxide, zirconium oxide, lanthanum oxide, niobium oxide, tungsten oxide, tin oxide, indium oxide, indium tin oxide, strontium oxide, vanadium oxide or molybdenum oxide.

29. The photovoltaic device of claim 1 where the thickness of the porous coating layer is substantially the same around the periphery of the axial cross section of the first conductor.

30. The photovoltaic device of claim 1 where there is substantially no barrier layer between the bottom of the pores and the surface of the first conductor.

31. The photovoltaic device of claim 1 where the semiconducting nanowires are made from one of either: Ge, GaSb, GaN, GaAs, InP, AlGaAs, InGaSb, InGaAsSb or GaInNAs.

32. The photovoltaic device of claim 31 where there is substantially no oxide layer between the semiconducting nanowire and the semiconducting layer.

33. The photovoltaic device of claim 31 where there is substantially no barrier layer between the bottom of the pores and the surface of the first conductor.

34. (canceled)

35. The photovoltaic device of claim 34 where the band gap is less than approximately 2 electron-volts.

36. The photovoltaic device of claim 34 where the band gap is less than approximately 1 electron-volts.

37. The photovoltaic device of claim 1 where the semiconducting layer is one of either: Polyacetylene, Polythiophene, Poly(3-alkyl)thiophene, Polypyrrole, Polyisothiaphthene, Polyetheltene dioxythiophene, Polyparaphenelyne vinylene, Poly (2,5 dialkoxy)paraphenylene, Polyparaphenylene, Polyparaphenylene sulphide, Polyheptadiyne or Poly 3-hexylthiophene poly(1,4-phenylene vinylene), poly(pyrrole), and polyacetylene.

38. The photovoltaic device of claim 37 where the semiconducting layer is doped to have a complementary charge carrying property relative to the semiconducting nanowires.

39. The photovoltaic device of claim 1 where the semiconducting layer is Polyanaline.

40. The photovoltaic device of claim 39 where the polyanaline is doped to have a complementary charge carrying property relative to the semiconducting nanowires.

41. The photovoltaic device of claim 39 where the dopant is one of either: dodecylbenzene sulfonic acid, camphor-sulfonic acid, p-toluenesulfonic acid, AsF₃, I₂, CN.

42. The photovoltaic device of claim 1 where the second conducting layer is Indium Tin Oxide.

43. The photovoltaic device of claim 1 where the second conducting layer is Invisicon.

44-49. (canceled)

50. The photovoltaic device of claim 17 where the nanowires extend at least approximately 1 micron past the outer surface of the porous layer.

51. The photovoltaic device of claim 18 where the nanowires extend at least approximately 5 microns past the outer surface of the porous layer.

52-76. (canceled)

77. A photovoltaic device comprising silicon nanowires where the spectral absorption is greater than approximately 50% for radiation wavelengths between approximately 450 nanometers and 2500 nanometers.

78. The photovoltaic device of claim 1 where the silicon nanowires have a spectral absorption greater than approximately 50% for radiation wavelengths between approximately 450 nanometers and 2500 nanometers.

79. The photovoltaic device of claim 77 further comprising: a semiconducting layer, a substantially transparent conducting layer, and a conducting layer, whereby the silicon nanowires are electrically connected to the conducting layer and extend into the semiconducting layer through an insulating porous layer.

80-81. (canceled)

82. A nanostructured electrical device comprising:
A first conductor with a surface;
An insulating porous layer with a top and bottom surface that covers a portion of the surface of the first conductor, the top surface of the porous layer opposing the surface of the first conductor, said porous layer having a plurality of pores, each pore having a first and second opening at the top and bottom surface of the porous layer, respectively;
A plurality of extrinsic semiconducting nanowires of a first type, each with two ends, where at least one of the semiconducting nanowires pass through one of the pores such that the first end of said at least one semiconducting nanowires is electrically connected to the first conductor in proximity to the second opening of the pore and the second end of the at least one semiconducting nanowires extends substantially past the first opening of the pore and is in operative contact with a semiconductor of a second type.

83. The nanostructured electrical device of claim 82 where the semiconducting nanowire is comprised of silicon.

84. The nanostructured electrical device of claim 82 where the semiconducting nanowire is substantially monocrystalline.

85. The nanostructured electrical device of claim 82 where the semiconducting nanowire is comprised of GaSb.

86. The nanostructured electrical device of claim 82 where there is substantially no barrier layer between the bottom of the pores and the surface of the first conductor.

87. The nanostructured electrical device of claim 82 where the semiconducting nanowire extends between approximately 500 nanometers and 30 microns past the top surface of the porous layer.

88. The nanostructured electrical device of claim 82 where the semiconducting nanowire extends between approximately 30 microns and 120 microns past the top surface of the porous layer.

89. The nanostructured electrical device of claim 82 where there the plurality of semiconducting nanowires are spaced between approximately 50 nanometers and 500 nanometers center to center.

90. The nanostructured electrical device of claim 82 where the thickness of the porous layer is between approximately 50 nanometers and 50 microns.

91. The nanostructured electrical device of claim 82 where the thickness of the porous layer is between approximately 2 microns and 8 microns.

92. The nanostructured electrical device of claim 82 where the porous layer is anodic aluminum oxide.

93. The nanostructured electrical device of claim 82 where the porous layer is one of either: titania, silica, zinc oxide, zirconium oxide, lanthanum oxide, niobium oxide, tungsten oxide, tin oxide, indium oxide, indium tin oxide, strontium oxide, vanadium oxide or molybdenum oxide.

94. The nanostructured electrical device of claim 82 where the semiconducting nanowires are made from one of either: Ge, GaN, GaAs, InP, AlGaAs, InGaSb, InGaAsSb or GaInNAs.

95. The nanostructured electrical device of claim 82 where the band gap of the first semiconductor type is between approximately 0.38 and 0.7 electron-volts.

96. The nanostructured electrical device of claim 82 where the first conductor is a metal and the porous layer is an oxide of the same metal.

97. The nanostructured electrical device of claim 96 where the metal is Aluminum.

98. The nanostructured electrical device of claim 82 where the porous layer is an oxide formed by anodizing a portion of the first conductor.

99. The nanostructured electrical device of claim 82 where the semiconducting nanowires comprising the nanostructured electrical device have a spectral absorption greater than approximately 50% for radiation wavelengths between approximately 450 nanometers and 2500 nanometers.

100. The nanostructured electrical device of claim 82 where the semiconductor of the second type is a polymer.

101. The nanostructured electrical device of claim 82 where a layer of an intrinsic semiconductor is situated between the first and second semiconductor layers such that the semiconducting nanowires are coated with the intrinsic semiconductor layer and are operatively connected to the second semiconductor type layer by an electrical path through the intrinsic semiconductor layer.

102. A method for making a nanostructured electrical device comprising:
Anodizing a metal layer in contact with the surface of a conducting layer to produce a porous metal oxide insulating layer comprised of a plurality of pores, each pore extending from a first surface of the oxide layer to the opposing second surface of the oxide layer, said first surface of the oxide layer being in proximity to the surface of the conducting layer;
Growing a plurality of extrinsic semiconducting nanowires such that at least one of the plurality of semiconducting nanowires grows through at least one of the plurality of pores and makes electrical contact with the conducting layer and extends from the surface of the conducting layer substantially past the opposing second surface of the porous oxide layer;
Coating a substantial portion of the semiconducting nanowires extending past the oxide layer with a semiconductor of a second type.

103. The method of claim 102 where the anodization step further comprises substantially clearing at least one of the plurality of pores of material that would impede the electrical connection between the semiconducting nanowires and the first conductor.

104. The method of claim 103 where the clearing step is comprised of a chemical etch process.

105. The method of claim 102 where the anodization step further comprises monitoring the steady state anodization current over time and stopping the anodization current upon the detection of a substantial increase in the anodization current over the steady state current.

106. The method of claim 105 where the substantial increase in anodization current is approximately two to three times the anodization current prior to the increase.

107. The method of claim 105 where the anodization step comprises a sequence of decreasing of the anodization voltage or the anodization current in a series of at least one step during the last 5% of the anodization process.

108. The method of claim 107 where the anodization step is comprised of anodizing at a first anodization voltage and then reducing the anodization voltage from the first anodization voltage to a second anodization voltage, monitoring the anodization current at the second anodization voltage, detecting the state where the anodization current has approximately plateaued and decreasing the anodization voltage to a third anodization voltage.

109. The method of claim 108 where the difference between the first anodization voltage and second anodization voltage is in the range from approximately 5% to 25% of the first anodization voltage.

110. The method of claim 102 where the growing step is a catalytic VLS technique.

111. The method of claim 110 where the growing step is further comprised of depositing a catalytic seed in at least one of the plurality of pores and etching substantially all of the catalytic seed from the tip of the at least one semiconducting nanowires growing out of said at least one pore.

112. The method of claim 111 where the catalytic seeds are one of either: tin, aluminum, copper, platinum, palladium, nickel or gallium.

113. The method of claim 102 where the step of coating the silicon nanowires is further comprised of substantially removing any oxide from the semiconducting nanowires prior to coating the semiconducting nanowires with the semiconducting layer.

114. The method of claim 102 where the growing step is further comprised of a catalysis where the catalytic reaction occurs in an ambient pressure between 1 and 13 Torr.
